(19) United States
(12) Patent Application Publication
(10) Pub. No.: US 2006/0071695 A1
(43) Pub. Date: Apr. 6, 2006

(54) Signal driving circuits including inverters

(75) Inventor: Jae-Woong Lee, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/220,448

(22) Filed: Sep. 7, 2005

(30) Foreign Application Priority Data
Oct. 5, 2004 (KR) 10-2004-0079283

(51) Int. Cl. H03B 1/00

(52) U.S. Cl. 327/112

(57) ABSTRACT

An input signal driving circuit includes first and second inverters that are connected in parallel between first and second reference voltages. The first and second inverters include first and second input terminals that are electrically connected together to define a common input terminal for the input signal. The first and second inverters also include first and second output terminals that are electrically connected together to define a common output terminal for an output signal. The first inverter has larger current driving capability than the second inverter. A feedback circuit is configured to feed back delayed versions of the output signal to the first and second inverters.

### CROSS-REFERENCE TO RELATED APPLICATION

This application claims the benefit under 35 USC § 119 of Korean Patent Application No. 2004-0079283, filed on Oct. 5, 2004, the disclosure of which is hereby incorporated herein by reference in its entirety as if set forth fully herein.

### FIELD OF THE INVENTION

The present invention relates to electronic circuits and, more particularly, to signal driving circuits.

### BACKGROUND OF THE INVENTION

In general, a signal driving circuit of that may be used in a semiconductor integrated circuit is comprised of a plurality of drivers which are cascade-connected. Each of the drivers may include inverters.

FIG. 1 shows an inverter used in a conventional signal driving circuit 100. The inverter of FIG. 1 includes a PMOS transistor 5 and an NMOS transistor 7 which are serially-connected between a power supply voltage (also referred to as a power voltage) and a ground voltage.

In the signal driving circuit 100 of FIG. 1, an excessive current path 15 may be temporarily formed between the power voltage and the ground voltage during signal transition, so that unnecessary current consumption may occur. Moreover, power noise may occur and signal transmission speed may be lowered. These potentially undesirable characteristics may occur because the PMOS transistor 5 may be continually maintained in an active state in order to maintain an output signal OUT having a high level when the output signal OUT is transited to a high level in response to an input signal IN having a low level. That is, when the input signal IN is transited from a low level to a high level, there may exist a time period where both the PMOS transistor 5 and the NMOS transistor 7 are active, thus creating the path 15 through which a current flows from the power voltage terminal to the ground voltage terminal. Such phenomenon may occur not only where the input signal IN is transited from a low level to a high level but also where the input signal IN is transited from a high level to a low level.

As described above, in a plurality of inverters which may constitute the conventional signal driving circuit, a signal may be transmitted with excessive current consumption during signal transition. This may create power noise and/or the signal transmission speed may be lowered.

### SUMMARY OF THE INVENTION

Input signal driving circuits according to exemplary embodiments of the present invention include first and second inverters that are connected in parallel between first and second reference voltages (such as power supply and ground voltages). The first and second inverters include first and second input terminals that are electrically connected together to define a common input terminal for the input signal, and respective first and second output terminals that are electrically connected together to define a common output terminal for the output signal. The first inverter has a larger current driving capacity than the second inverter. A feedback circuit is configured to feed back delayed versions of the output signal to the first and second inverters.

In some embodiments, the feedback circuit is configured to delay and invert the output signal to produce a delayed and inverted signal that is fed back to the second inverter, and to further delay and further invert the output signal to produce a further delayed and further inverted signal that is feed back to the first inverter. In other embodiments, the feedback circuit is configured to delay the output signal to produce a delayed signal that is fed back to the second inverter and to further delay the output signal to produce a further delayed signal that is fed back to the first inverter. In still other embodiments, the feedback circuit is configured to invert the output signal to produce an inverted signal that is fed back to the second inverter, and to further invert the output signal to produce a further inverted signal that is fed back to the first inverter.

According to other exemplary embodiments of the present invention, a signal driving circuit includes a main driving circuit. The main driving circuit includes a first main driving portion that is configured to pull up an output signal in response to an input signal and a first state of a first signal which is a delayed output signal, and a second main driving portion that is configured to pull down the output signal in response to the input signal and a second state of the first signal. An auxiliary driving circuit includes a first auxiliary driving portion that is configured to pull up the output signal in response to the input signal and a first state of a second signal which is an inverted output signal, and a second auxiliary driving portion that is configured to pull down the output signal in response to the input signal and a second state of the second signal. A delay circuit is configured to invert the output signal to generate the first signal and to delay the output signal to generate the second signal. The first and second main driving portions have larger current driving capability than the first and second auxiliary driving portions.

In some embodiments, the second main driving portion and the first auxiliary driving portion are activated when the input signal transits from the first state to the second state. The second auxiliary driving portion is activated when the input signal is maintained in the second state. Moreover, the first main driving portion and the second auxiliary driving portion are activated when the input signal transits from the second state to the first state, and the first auxiliary driving portion is activated when the input signal is maintained in the first state.

In some embodiments, the first main driving portion includes two pull-up transistors which are serially-connected between a power supply voltage (also referred to as a power voltage) and an output signal generating terminal to generate the output signal and are turned on in response to the input signal and the first signal, respectively. The second main driving portion includes two pull-down transistors which are serially-connected between the output signal generating terminal and a ground voltage and are turned on in response to the first signal and the input signal, respectively. In some embodiments, each of the two pull-up transistors is a PMOS transistor, and each of the two pull-down transistors is an NMOS transistor.

In some embodiments, the first auxiliary driving portion includes two pull-up transistors which are serially-connected between a power voltage and an output signal generating terminal to generate the output signal and are turned on in response to the input signal and the second signal, respectively. The second auxiliary driving portion includes two pull-down transistors which are serially-connected between the output signal generating terminal and a ground voltage and are turned on in response to the second signal and the input signal, respectively. In some embodiments, each of the two pull-up transistors is a PMOS transistor, and each of the two pull-down transistors is an NMOS transistor. Moreover, in some embodiments, the delay circuit includes a first inverter that is configured to invert the output signal to generate the second signal, and a second inverter that is configured to invert the second signal to generate the first signal.

Signal driving circuits according to yet other embodiments of the present invention include a first inverter that is responsive to the input signal to produce an inverted output signal, a latch that is responsive to the inverted output signal to produce a driving circuit output signal, and a second inverter that is configured to invert the driving circuit output signal and to feed back the driving circuit output signal that is inverted to the first inverter. In some embodiments, the first inverter comprises first and second field effect transistors of a first conductivity type (such as PMOS transistors), and third and fourth field effect transistors of a second conductivity type (such as NMOS transistors), the controlled electrodes (e.g., the sources and drains) of all of which are serially-connected between first and second reference voltages (e.g., power supply and ground voltages). The input signal is connected to controlling electrodes (e.g., gates) of one of the first and second field effect transistors and one of the third and fourth field effect transistors. The driving circuit output signal that is inverted is connected to the controlling electrodes of the other of the first and second field effect transistors and the other of the third and fourth field effect transistors. Moreover, in some embodiments, the inverted output signal is defined between the controlled electrodes of one of the first and second field effect transistors and one of the third and fourth field effect transistors.

In still other exemplary embodiments of the present invention, a signal driving circuit includes a main driving circuit including a first main driving portion that is configured to pull up an output signal in response to a first state of an input signal and an inverted output signal, and a second main driving portion that is configured to pull down the output signal in response to a second state of the input signal and the inverted output signal. A latch is configured to store and latch the output signal of the main driving circuit. A delay circuit is configured to invert the output signal to generate the inverted output signal.

In some embodiments, the second main driving portion is activated when the input signal transits from the first state to the second state The first main driving portion is activated when the input signal transits from the second state to the first state. When the input signal is maintained to the first or second state, the first and second main driving portions are deactivated, and a latched signal is output from the latch circuit.

In some embodiments, the first main driving portion includes two pull-up transistors which are serially-connected between a power voltage and an output signal generating terminal of the main driving circuit and are turned on in response to the input signal and the inverted output signal, respectively. The second main driving portion includes two pull-down transistors which are serially-connected between the output signal generating terminal of the main driving circuit and a ground voltage and are turned on in response to the inverted output signal and the input signal, respectively. In some embodiments, each of the two pull-up transistors is a PMOS transistor, and each of the two pull-down transistors is an NMOS transistor.

Moreover, in some embodiments, the latch includes a first inverter that is configured to invert the output signal of the main driving circuit to generate the output signal, and a second inverter that is configured to invert the output signal and to output the inverted output to the first inverter. The delay circuit can include at least one inverter.

### BRIEF DESCRIPTION OF THE DRAWINGS

FIG. 1 is a circuit diagram of a conventional signal driving circuit;

FIG. 2 is a circuit diagram of a signal driving circuit according to exemplary embodiments of the present invention; and

FIG. 3 is a circuit diagram of a signal driving circuit according to other exemplary embodiments of the present invention.

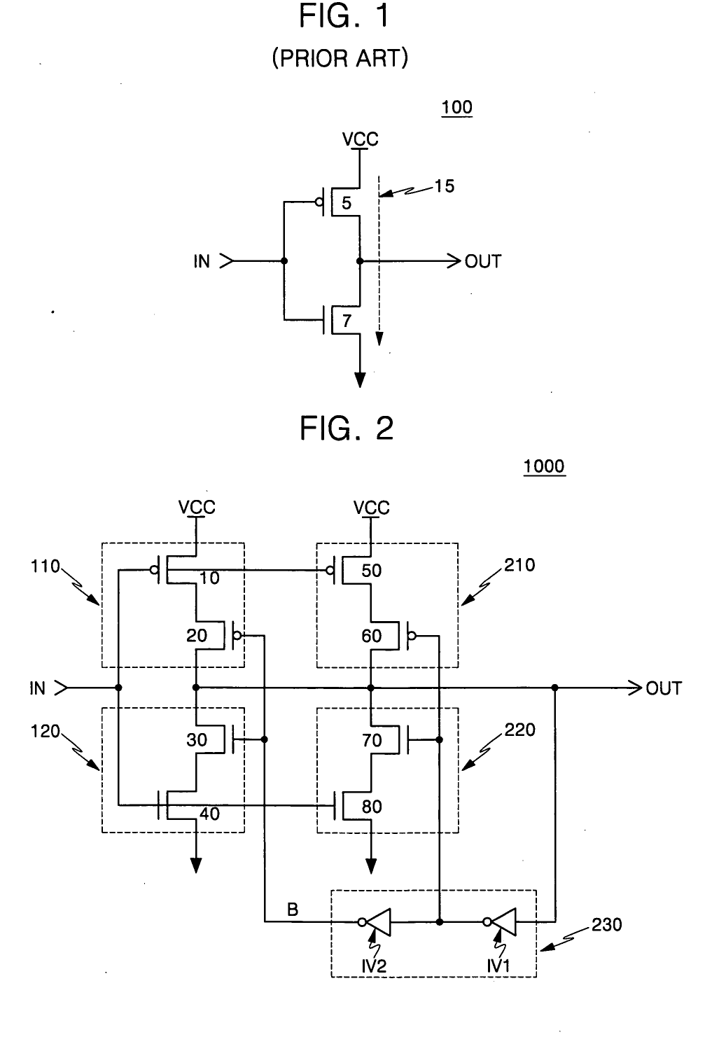

### DETAILED DESCRIPTION

The present invention now will be described more fully hereinafter with reference to the accompanying drawings, in which illustrative embodiments of the invention are shown. However, this invention may be embodied in many different forms and should not be construed as limited to the embodiments set forth herein. Rather, these embodiments are provided so that this disclosure will be thorough and complete, and will fully convey the scope of the invention to those skilled in the art.

It will be understood that when an element is referred to as being “coupled”, “connected” or “responsive” to another element, it can be directly coupled, connected or responsive to the other element or intervening elements may also be present. In contrast, when an element is referred to as being “directly coupled”, “directly connected” or “directly responsive” to another element, there are no intervening elements present. Like numbers refer to like elements throughout. As used herein the term “and/or” includes any and all combinations of one or more of the associated listed items and may be abbreviated by “/”. Moreover, each embodiment described and illustrated herein includes its complementary conductivity type embodiment as well.

It will also be understood that, although the terms first, second, etc. may be used herein to describe various elements, these elements should not be limited by these terms. These terms are only used to distinguish one element from another element.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, steps, operations, elements, and/or components, but do not preclude the presence or addition of one or more other features, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

FIG. 2 is a circuit diagram of a signal driving circuit according to exemplary embodiments of the present invention. The signal driving circuit 1000 of FIG. 2 includes a main driving circuit 110 and 120 and an auxiliary driving circuit 210 and 220.

The main driving circuit 110 and 120 includes a first main driving portion 110 that is configured to pull up an output signal OUT, and a second main driving portion 120 that is configured to pull down the output signal OUT. In some embodiments, the first main driving portion 110 includes PMOS transistors 10 and 20 which are serially-connected between a power voltage terminal VCC and an output signal OUT generating terminal and are turned on in response to an input signal IN and a signal B, respectively. The second main driving portion 120 includes NMOS transistors 30 and 40 which are serially-connected between the output signal OUT generating terminal and a ground voltage terminal and are turned on in response to the signal B and the input signal IN, respectively. The output signal OUT is generated through a common connection of the PMOS transistor 20 and the NMOS transistor 30.

In some embodiments, the auxiliary driving circuit 210 and 220 includes a first auxiliary driving portion 210 that is configured to assist in pulling up the output signal OUT and a second auxiliary driving portion 220 that is configured to assist in pulling down the output signal OUT. The first auxiliary driving portion 210 includes PMOS transistors 50 and 60 which have the same connection as the first main driving portion 110, and the second auxiliary driving portion 220 includes NMOS transistors 70 and 80 which have the same connection as the second main driving portion 120. The output signal OUT is generated through a common connection of the PMOS transistor 60 and the NMOS transistor 70.

In some embodiments, the PMOS transistors 10 and 20 and the NMOS transistors 30 and 40 which constitute the first and second main driving portions 110 and 120 have relatively larger channel width than the PMOS transistors 50 and 60 and the NMOS transistors 70 and 80 which constitute the first and second auxiliary driving portions 210 and 220. Thus, a larger current driving capability may be provided.

Operation of a signal driving circuit of FIG. 2 according to exemplary embodiments of the invention is described below.

First, if the input signal IN transits from a high level to a low level in the state that the output signal OUT has a low level, the PMOS transistor 60 is turned off and the NMOS transistor 70 is turned on in response to an output signal of the inverter IV1 having a high level. In response to an output signal of the inverter IV2 having a low level, in the state that the PMOS transistor 20 is turned on and the NMOS transistor 30 is turned off, the PMOS transistors 10 and 50 are turned on and the NMOS transistors 40 and 80 are turned off. Thus, the first main driving portion 110 is activated, and the first auxiliary driving portion 210 and the second main driving portion 120 are deactivated. Thus, the output signal OUT transits to a high level by the first main driving portion 110, and even though the first main driving portion 110 and the second auxiliary driving portion 220 are simultaneously activated during a time period where the input signal IN transits from a high level to a low level, since driving capability of the second auxiliary driving portion 220 is small, consumption of a current which flows from the power voltage terminal VCC to the ground voltage terminal can become small.

When the input signal IN maintains a low level and the output signal OUT maintains a high level, in response to an output signal of the inverter IV1 having a low level, the PMOS transistor 60 is turned on and the NMOS transistor 70 is turned off, and in response to an output signal of the inverter IV2 having a high level, the PMOS transistor 20 is turned off and the NMOS transistor 30 is turned off. Thus, only the first auxiliary driving portion 210 is activated to maintain the output signal OUT having a high level.

In contrast, if the input signal IN transits from a low level to a high level in a state that the output signal OUT has a high level, the PMOS transistor 60 and the NMOS transistor 30 are turned on and the PMOS transistor 20 and the NMOS transistor 70 are turned off, the NMOS transistors 40 and 80 are turned on, and the PMOS transistors 10 and 50 are turned off. Thus, the second main driving portion 120 is activated, and the second auxiliary driving portion 220 and the first main driving portion 110 are deactivated. As a result, the output signal OUT transits to a low level by the second main driving portion 120, and even though the second main driving portion 120 and the first auxiliary driving portion 210 are simultaneously activated during a time period where the input signal IN transits from a low level to a high level, since the driving capability of the first auxiliary driving portion 120 is small, consumption of a current which flows from the power voltage terminal VCC to the ground voltage terminal can be small.

When the input signal IN maintains a high level and the output signal OUT maintains a low level, only the second auxiliary driving portion 220 is activated to maintain the output signal having a low level.

As described above, in the signal driving circuit of FIG. 2, when the input signal IN transits from a high level to a low level, even though the first main driving portion 110 and the second auxiliary driving portion 220 are simultaneously activated, since the driving capability of the second auxiliary driving portion 220 is relatively small compared to that of the first main driving portion 110, consumption of current which flows from the power voltage terminal VCC to the ground voltage terminal can be reduced. Similarly, when the input signal IN transits from a low level to a high level, even though the second main driving portion 120 and the first auxiliary driving portion 210 are simultaneously activated, since driving capability of the first auxiliary driving portion 210 is relatively small compared to that of the second main driving portion 120, consumption of current which flows from the power voltage terminal VCC to the ground voltage terminal can be reduced.

That is, in a signal driving circuit according to exemplary embodiments of the present invention, when the input signal IN transits from a high level to a low level or from a low level to a high level, since the first main driving portion 110 or the second main driving portion 120 is selectively deactivated by an output signal of a delay circuit 230, an undesired current path formed between the power voltage VCC terminal and the ground voltage terminal of the first and second main driving portions 110 and 120 can be reduced or minimized. Also, the slew rate of the output signal OUT can be improved by selectively controlling pull-up or pull-down driving capabilities of the first and second driving portions 110 and 120 according to state of the input signal IN during transition. As a result, a transmission rate of the input signal IN can be improved.

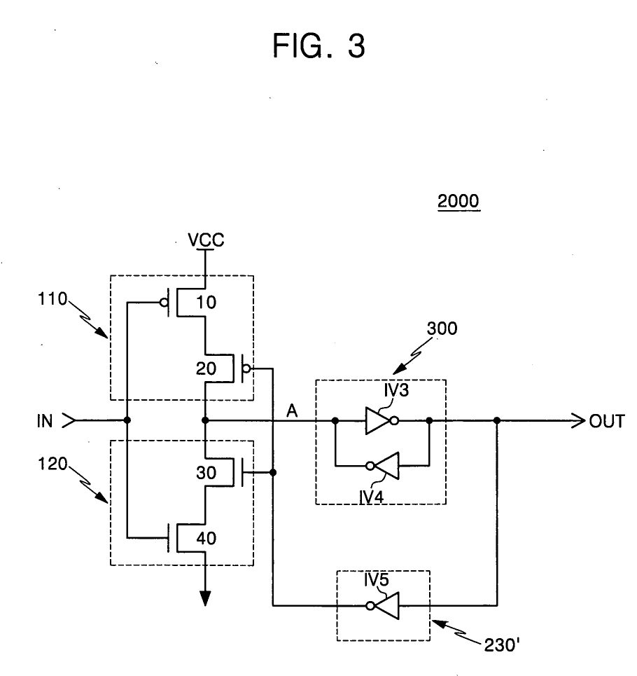

FIG. 3 is a circuit diagram illustrating a signal driving circuit according to other exemplary embodiments of the present invention. The first and second main driving portions 110 and 120 of a signal driving circuit 2000 are the same as those of FIG. 2. A latch 300 and a delay circuit 230′ are provided. The latch 300 can include inverters IV3 and IV4, and the delay circuit 230′ can include an inverter IV5.

Operation of a signal driving circuit of FIG. 3 according to exemplary embodiments of the invention is described below.

First, if an input signal IN transits from a high level to a low level when an output signal OUT maintains a high level, the PMOS transistor 10 is turned on, and the NMOS transistor 40 is turned off. Also, since an output signal of the inverter IV5 has a low level, the PMOS transistor 20 is turned on, and the NMOS transistor 30 is turned off. That is, when the input signal IN transits from a high level to a low level, even through the PMOS transistor 10 and the NMOS transistor 40 are simultaneously turned on, since the NMOS transistor 30 is turned off, little or no consumption of current which flows from a power voltage VCC terminal to a ground voltage terminal may occur. Also, the first main driving portion 110 is activated, and the second main driving portion 120 is deactivated, so that a signal A transits to a high level. The latch 300 inverts the signal A having a high level to transit the output signal OUT to a low level and latches and maintains the output signal OUT having a low level.

In contrast, if the input signal IN transits from a low level to a high level when the output signal OUT maintains a low level, the PMOS transistor 10 is turned off, and the NMOS transistor 40 is turned on. Also, since the output signal of the inverter IV5 has a high level, the PMOS transistor 20 is turned off, and the NMOS transistor 30 is turned on. That is, when the input signal IN transits from a low level to a high level, even through the PMOS transistor 10 and the NMOS transistor 40 are simultaneously turned on, since the PMOS transistor 20 is turned off, consumption of a current which flows from a power voltage VCC terminal to a ground voltage terminal may be reduced or minimized. Also, the second main driving portion 120 is activated, and the first main driving portion 110 is deactivated, so that the signal A transits to a low level. The latch 300 inverts the signal A having a low level to transit the output signal OUT to a high level and latches and maintains the output signal OUT having a high level.

Accordingly, the signal driving circuit of FIG. 3 can reduce or minimize consumption of current which flows from the power voltage VCC terminal to the ground voltage terminal such that only the first main driving portion 110 is activated when the input signal IN transits from a high level to a low level and only the second main driving portion 120 is activated when the input signal IN transits from a low level to a high level.

As described above, signal driving circuits according to some embodiments of the present invention include the auxiliary driving circuit and the delay circuit coupled to the output terminal of the main driving circuit so that the main driving circuit can be controlled by using the output signal of the delay circuit. Moreover, signal driving circuits according to other embodiments of the invention include the latch and the delay circuit coupled to the output terminal of the main driving circuit so that the main driving circuit can be controlled by using the output signal of the delay circuit. Undesirable consumption of current which flows through the main driving circuit during transition of the input signal can be reduced, thereby reducing power consumption and allowing higher signal transmission rate.

In the embodiments described above, the respective driving circuits include inverters, but the driving circuits can include various logic circuits as well.

As described herein, signal driving circuits according to exemplary embodiments of the present invention can selectively deactivate the pull-up or pull-down driving circuit of the main driving circuit during transition of the input signal. As a result, consumption of current which flows through the main driving circuit can be reduced. Also, the slew rate of the output signal of the main driving circuit can be increased by selectively deactivating the first or second main driving circuit and selectively activating the first or second auxiliary driving circuit according to the state of the output signal.

Thus, using the signal driving circuits according to exemplary embodiments of the present invention, power consumption can be reduced and/or data access speed can be increased.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A signal driving circuit, comprising:
a main driving circuit including a first main driving portion that is configured to pull up an output signal in response to an input signal and a first state of a first signal which is a delayed output signal, and a second main driving portion that is configured to pull down the output signal in response to the input signal and a second state of the first signal;
an auxiliary driving circuit including a first auxiliary driving portion that is configured to pull up the output signal in response to the input signal and a first state of a second signal which is an inverted output signal, and a second auxiliary driving portion that is configured to pull down the output signal in response to the input signal and a second state of the second signal; and
a delay circuit that is configured to invert the output signal to generate the first signal and to delay the output signal to generate the second signal,
wherein the first and second main driving portions have larger current driving capability than the first and second auxiliary driving portions.

2. The circuit of claim 1, wherein the second main driving portion and the first auxiliary driving portion are activated when the input signal transits from the first state to the second state,
the second auxiliary driving portion is activated when the input signal is maintained in the second state,
the first main driving portion and the second auxiliary driving portion are activated when the input signal transits from the second state to the first state, and
the first auxiliary driving portion is activated when the input signal is maintained in the first state.

3. The circuit of claim 2, wherein the first main driving portion includes two pull-up transistors which are serially-connected between a power voltage and an output signal generating terminal to generate the output signal and are turned on in response to the input signal and the first signal, respectively, and the second main driving portion includes two pull-down transistors which are serially-connected between the output signal generating terminal and a ground voltage and are turned on in response to the first signal and the input signal, respectively.

4. The circuit of claim 3, wherein each of the two pull-up transistors is a PMOS transistor, and each of the two pull-down transistors is an NMOS transistor.

5. The circuit of claim 2, wherein the first auxiliary driving portion includes two pull-up transistors which are serially-connected between a power voltage and an output signal generating terminal to generate the output signal and are turned on in response to the input signal and the second signal, respectively, and the second auxiliary driving portion includes two pull-down transistors which are serially-connected between the output signal generating terminal and a ground voltage and are turned on in response to the second signal and the input signal, respectively.

6. The circuit of claim 5, wherein each of the two pull-up transistors is a PMOS transistor, and each of the two pull-down transistors is an NMOS transistor.

7. The circuit of claim 1, wherein the delay circuit includes a first inverter that is configured to invert the output signal to generate the second signal, and a second inverter that is configured to invert the second signal to generate the first signal.

8. A signal driving circuit, comprising:
a main driving circuit including a first main driving portion that is configured to pull up an output signal in response to a first state of an input signal and an inverted output signal, and a second main driving portion that is configured to pull down the output signal in response to a second state of the input signal and the inverted output signal;
a latch that is configured to store and latch the output signal of the main driving circuit; and
a delay circuit that is configured to invert the output signal to generate the inverted output signal.

9. The circuit of claim 8, wherein the second main driving portion is activated when the input signal transits from the first state to the second state,
the first main driving portion is activated when the input signal transits from the second state to the first state, and
when the input signal is maintained in the first or second state, the first and second main driving portions are deactivated, and a latched signal is output from the latch circuit.

10. The circuit of claim 8, wherein the first main driving portion includes two pull-up transistors which are serially-connected between a power voltage and an output signal generating terminal of the main driving circuit and are turned on in response to the input signal and the inverted output signal, respectively, and the second main driving portion includes two pull-down transistors which are serially-connected between the output signal generating terminal of the main driving circuit and a ground voltage and are turned on in response to the inverted output signal and the input signal, respectively.

11. The circuit of claim 10, wherein each of the two pull-up transistors is a PMOS transistor, and each of the two pull-down transistors is an NMOS transistor.

12. The circuit of claim 8, wherein the latch includes a first inverter that is configured to invert the output signal of the main driving circuit to generate the output signal, and a second inverter that is configured to invert the output signal and to output the inverted output to the first inverter.

13. The circuit of claim 8, wherein the delay circuit includes at least one inverter.

14. An input signal driving circuit comprising:
first and second inverters that are connected in parallel between first and second reference voltages, the first and second inverters including respective first and second input terminals that are electrically connected together to define a common input terminal for the input signal and respective first and second output terminals that are electrically connected together to define a common output terminal for an output signal, the first inverter having larger current driving capability than the second inverter; and
a feedback circuit that is configured to feed back delayed versions of the output signal to the first and second inverters.

15. The circuit of claim 14 wherein the feedback circuit is configured to delay and invert the output signal to produce a delayed and inverted signal that is fed back to the second inverter, and to further delay and further invert the output signal to produce a further delayed and further inverted signal that is fed back to the first inverter.

16. The circuit of claim 14 wherein the feedback circuit is configured to delay the output signal to produce a delayed signal that is fed back to the second inverter, and to further delay the output signal to produce a further delayed signal that is fed back to the first inverter.

17. The circuit of claim 14 wherein the feedback circuit is configured to invert the output signal to produce an inverted signal that is fed back to the second inverter, and to further invert the output signal to produce a further inverted signal that is fed back to the first inverter.

18. An input signal driving circuit comprising:
a first inverter that is responsive to the input signal to produce an inverted output signal;
a latch that is responsive to the inverted output signal to produce a driving circuit output signal; and
a second inverter that is configured to invert the driving circuit output signal and to feed back the driving circuit output signal that is inverted to the first inverter.

19. The circuit of claim 18 wherein the first inverter comprises first and second field effect transistors of a first conductivity type and third and fourth field effect transistors of a second conductivity type, the controlled electrodes of all of which are serially connected between first and second reference voltages; wherein the input signal is connected to the controlling electrodes of one of the first and second field effect transistors and one of the third and fourth field effect transistors and wherein the driving circuit output signal that is inverted is connected to the controlling electrodes of the other of the first and second field effect transistors and the other of the third and fourth field effect transistors.

20. The circuit of claim 19 wherein the inverted output signal is defined between the controlled electrodes of one of the first and second field effect transistors and one of the third and fourth field effect transistors.
